(19) United States
(12) Patent Application Publication
(10) Pub. No.: US 2010/0055562 A1
(43) Pub. Date: Mar. 4, 2010

(54) NANOWIRE LAYER ADHESION ON A SUBSTRATE

(75) Inventors: Yong Hyup Kim, Seoul (KR); Eui Yun Jang, Jeju-do (KR)

Correspondence Address: KNOBBE MARTENS OLSON & BEAR LLP, 2040 MAIN STREET, FOURTEENTH FLOOR, IRVINE, CA, 92614, US

(73) Assignee: Seoul National University Industry Foundation, Seoul (KR)

(21) Appl. No.: 12/199,742

(22) Filed: Aug. 27, 2008

(51) Int. Cl. H01M 4/02; H01B 13/004; C23C 14/02; B32B 5/16

(52) U.S. Cl. 429/209; 427/534; 428/323

(57) ABSTRACT

Techniques for forming nanowire layers on a substrate are provided.

### BACKGROUND

1. Technical Field

The present disclosure relates generally to nanotechnology and, more particularly, to nanowire layer adhesion.

2. Description of Related Art

The current trend of electronic products becoming smaller and thinner has led to the use of various thin film members. In general, thin films may be formed using deposition methods such as sputtering, vapor deposition, and the like.

As a representative thin film member, a transparent electrode may be manufactured by depositing transparent conductive materials such as Indium Tin Oxide (ITO) on a transparent substrate.

While crystalline thin films such as ITO, and the like, exhibit adhesive strength with the substrate, such films may be difficult to employ in electronic products requiring flexibility.

On the other hand, conventional flexible thin films formed, for example, from nano fibers, tend to exhibit weaker adhesive strength between the nano fiber and the substrate, thereby reducing the durability of the electronic products and increasing contact resistance, resulting in deterioration of the electrical characteristics of the products.

### SUMMARY

In one embodiment, a method for forming a nanowire layer includes etching a substrate with an ionized gas, coating the etched substrate with a solution containing nanowires, and drying the substrate.

In another embodiment, a method for forming a carbon nanotube (CNT) layer includes preparing CNTs, purifying the CNTs, dispersing the purified CNTs in a solvent to form a CNT-containing solution, coating an etched substrate with the CNT-containing solution, and drying the coated substrate.

The Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIG. 1 is a schematic sectional diagram of an illustrative embodiment showing the etching of a surface of a substrate using an ionized gas;

FIG. 2 is a sectional diagram illustrating the substrate of FIG. 1 after it has been etched using the ionized gas;

FIG. 3 is a sectional diagram illustrating a nanowire layer formed on the substrate of FIG. 2;

FIG. 4 depicts a sectional diagram obtained by magnifying ‘A’ of FIG. 3;

FIG. 5 depicts a scanning electron microscope (SEM) micrograph showing a nanowire layer according to an illustrative embodiment; and

FIG. 6 is a sectional diagram of an illustrative embodiment of a transparent electrode.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the components of the present disclosure, as generally described herein, and illustrated in the Figures, may be arranged, substituted, combined, and designed in a wide variety of different configurations, all of which are explicitly contemplated and make part of this disclosure.

The embodiment(s) described, and references in the specification to “one embodiment”, “an embodiment”, “an example embodiment”, etc., indicate that the embodiment(s) described may include a particular feature, structure, or characteristics, but every embodiment may not necessarily include the particular feature, structure, or characteristics, but every embodiments may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

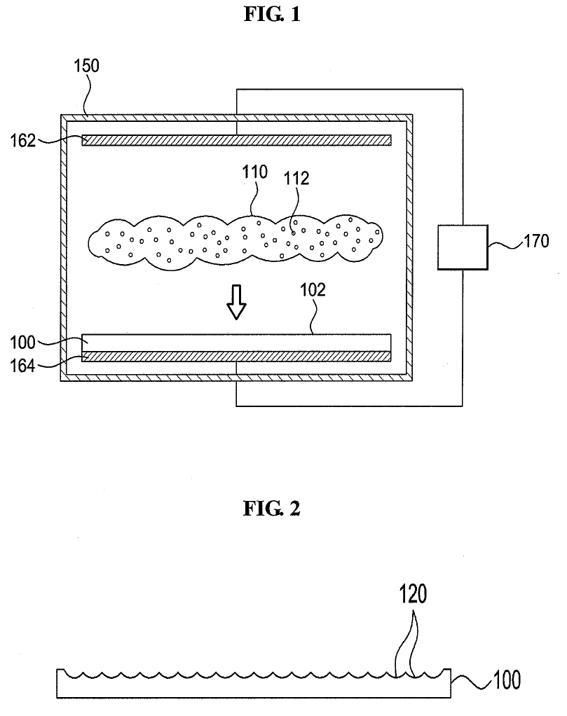

FIGS. 1 to 3 depict schematic sectional diagram illustrating an illustrative embodiment of the formation of a nanowire layer on a substrate. FIG. 1 is a schematic sectional diagram illustrating an illustrative embodiment of the etching of a surface 102 of a substrate 100 using an ionized gas 110. Ionized gas 110 includes ionized (or radicalized) particles 112 used to etch surface 102 of substrate 100 in, for example, an etching chamber 150. The etching of surface 102 may be performed by an interaction with ionized gas 110 when an electric field is applied to etching chamber 150. The electric filed is generated when an electric power is provided to electrodes 162, 164 from a power supply 170. The electric field is formed between electrodes 162, 164. After the etching is completed, surface 102 of substrate 100 may be physically etched and/or chemically modified.

Substrate 100 may include, by way of non-limiting example, a silicon substrate, a glass substrate, an oxide substrate, a polymeric substrate, and the like. The material employed for substrate 100 may vary depending on a use of the substrate 100. By way of example, substrate 100 applicable for use in a transparent electrode may include transparent substrates such as a glass substrate, an oxide substrate, a transparent resin film, and the like. Further, substrate 100 may be cleaned to remove foreign substances on substrate 100 before performing the etching process described herein. The transparent resin film may include, by way of non-limiting example, a polyethylene terephthalate (PET) film.

The term substrate, as used herein, may include both a thick or bulky-typed substrate and a thin film having a nano or micro sized structure. Such a thin film may include, by way of non-limiting example metal thin films formed through metal deposition using metals such as aluminum, copper, and the like. Such metal thin films may be transparent.

Ionized gas 110 may be generated by providing electric power from power supply 170 to electrodes 162, 164 in etching chamber 150 including a source gas. The electric field is formed when the electric power is provided to electrodes 162, 164. The source gas may be, by way of non-limiting example, provided to etching chamber 150 from an external source. When the electric field is formed in etching chamber 150, particles or elements within the source gas may be converted into ionized (or radicalized) particles 112. Ionized particles 112 may collide with substrate 100 in response to the electric field. Further, substrate 100 may be electrically charged while the electric field is formed in etching chamber 150. Subsequently, surface 102 of substrate 100 may be physically etched and/or chemically modified by collisions with ionized particles 112

The strength of the applied electric field may vary according to a type of the source gas. As a non-limiting example, when using an oxygen(O₂) containing gas as the source gas, the source gas may be ionized by an electric field having an electric power of about 150 to 300 watts.

Ionized gas 110 may include, by way of example and not a limitation, group 16 elements, group 17 elements or any combination thereof. As a non-limiting example, ionized gas 110 may include elements such as oxygen (O), sulfur (S), selenium (Se), tellurium (Te), fluorine (F), chlorine (Cl), bromine (Br), iodine (I), astatine (At), and the like. Alternatively, the ionized gas 110 may include inert elements of group 18 elements such as helium (He), neon (Ne), argon (Ar), krypton (Kr), xenon (Xe), radon (Rn), and the like.

As a non-limiting example, the etching process described herein may be performed in a Reactive Ion Etching (RIE) device. An RIE device supplies Radio Frequency (RF) power to two parallel flat plate electrodes facing each other. The source gas may be provided to the space between the two parallel flat plate electrodes. When Radio Frequency (RF) power is supplied to the two parallel flat plate electrodes, the source gas may be activated to etch a target substrate. The activated source gas (ionized gas) 110 may chemically react with a portion of the substrate 100. In some implementations, the internal pressure of the RIE may be maintained in a vacuum state of about 30 to 50 mTorr while the etching process is performed.

FIG. 2 is a sectional diagram illustrating the substrate of FIG. 1 after having been etched using the ionized gas. Referring to FIG. 2, etched substrate 100 may have an uneven region 120 having a predetermined roughness. In addition to physically roughening the surface, the etching of substrate 100 may also chemically modify surface 102 of substrate 100. However, claimed subject matter is not limited with respect to how an ionized gas modifies a substrate surface. In some implementations, changes in roughness and light transmittance after the etching of a transparent substrate, such as a glass substrate, may be observed as will be described below in more detail.

Measurement of Changes in Roughness of Transparent Substrate Before and After Etching

Changes in roughness of a glass substrate after performing etching using an ionized gas may be observed. For example, substrate roughness before and after etching may be measured by scanning a relatively small surface area (e.g., a 4 μm² area) of the substrate using an Atomic force microscope (AFM). Etching as described herein may increase an average roughness of a substrate by an order of magnitude or more, although claimed subject matter is not limited in this regard. For example, etching as described herein has been measured to increase glass substrate roughness from about 0.8 nm before etching to about 20 nm after etching.

Measurement of Changes in Light Transmittance of Glass Substrate Before and After Etching

Changes in light transmittance of the transparent substrate after performing etching may also be observed. For example, etching as described herein may reduce transmittance of a glass substrate at shorter wavelengths by about 1% although claimed subject matter is not limited in this regard.

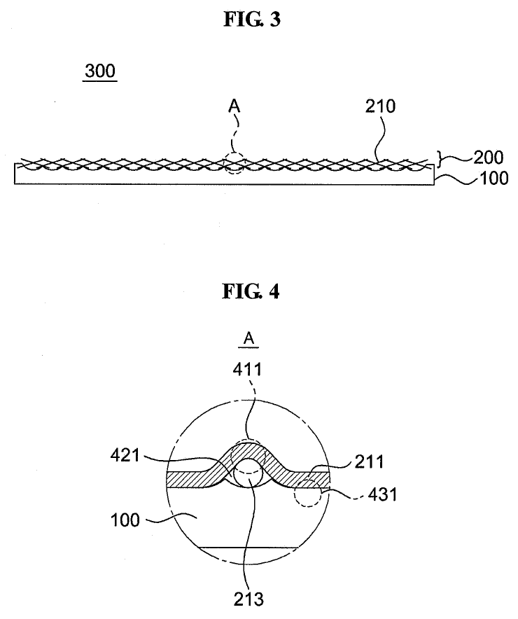

FIG. 3 is a sectional diagram illustrating a nanowire layer formed on the substrate of FIG. 2. Referring to FIG. 3, a thin film member 300 includes a substrate 100 and a nanowire layer 200. Thin film member 300 may be manufactured by forming nanowire layer 200 on surface 102 of substrate 100, where surface 102 of substrate 100 having been subjected to the above-described etching. Nanowire layer 200 includes nanowire materials 210. Nanowire materials 210 may be nano materials having a nano-sized diameter and length of several μm to several hundred μm, although claimed subject matter is not limited in this regard. Nanowire materials 210 may include, by way of non-limiting example, a carbon-based nanowire such as CNT, and a metal-based nanowire such as metal hydroxide, metal oxide, and the like. The CNT may have an anisotropic structure, and may be classified into Single Wall-CNT (SW-CNT), Multi-Wall CNT (MU-CNT), rope CNT, and the like.

Nanowire layer 200 may be formed by coating nanowire materials 210 onto substrate 100 using a nanowire-containing solution, and drying coated substrate 100. The solution containing the nanowire materials may be, by way of non-limiting example, a colloidal solution formed by evenly dispersing the nanowire materials in a solvent. The solvents used may vary depending on a type of the nanowire materials 210 employed. For example, solvents employed when using CNT for the nanowire materials 210 may include 1,2-Dichlorobenzene, Chloroform, 1-Methylnaphthalene, 1-Bromo-2-methoylnaphthalene, N-Methylpyrrolidinone, Dimethylformamide, Tetrahydrofuran, 1,2-Dimethylbenzene, Pyridine, Carbon disulfide, 1,3,5-Trimethylbenzene, and the like. Further, the nanowire-containing solution used to coat a substrate may include a single solvent or a mixture of solvents.

In addition, although claimed subject matter is not limited in this regard, nanowire materials 210 may undergo a preparation process before being mixed with the solvent to form the solution. To do so, nanowire materials 210 may be subjected to an ultrasonic treatment in an acidic solution such as, by way of non-limiting example, a nitric acid solution. Bundle-typed nanowire materials provided by nanowire-makers may be separated into individual nanowires by the ultrasonic treatment.

Further, the preparation process may act to remove catalyst from nanowire materials 210 and nanowire materials 210 may subsequently be coupled with a functional group such as, by way of non-limiting example, a hydroxy group derived form an acid solution. The coupled functional group may enhance the affinity of nanowire materials 210 for modified surface 102 of substrate 100. As a non-limiting example, functional groups such as a hydroxy group, a carboxyl group, and the like may be combined with nanowire materials 210.

The nanowire-containing solution may be coated on the surface of substrate 100 by various schemes such as, by way of non-limiting example, spin coating, spraying, dip-coating, and the like. The dip-coating scheme may be performed by immersing substrate 100 in the nanowire-contained solution. Once coated with the nanowire-containing solution, the solvent elements may be volatilized by drying leaving nanowire layer 200 including nanowire materials 210 on substrate 100.

Hereinafter, according to an illustrative embodiment, preparing a CNT-containing solution, as an example of the nanowire-containing solution, will be described in detail. However, this example is for illustrative purpose only, and should not be construed as limiting the scope of claimed subject matter.

Preparing a CNT-Containing Solution

In order to prepare an amount of SW-CNT for incorporation into a nanowire-containing solution the SW-CNT may be dispersed in a nitric acid solution and reacted with the nitric acid solution for 30 minutes at 50° C. Next, ultrasonic waves may be applied to the reaction solution so as to remove, as a non-limiting example, a catalyst associated with or bonded to the CNT. After completion of the reaction, the reaction solution may be neutralized with deionized water. Then, the neutralized reaction solution may be subjected to a filtering process, such as vacuum filtering, to remove the CNT from the solution. The removed CNT may be dried for about 48 hours at 80° C. in a vacuum oven chamber. The dried CNT may then be uniformly dispersed in a 1,2-Dichlorobenzene solvent to produce a CNT-containing solution of a colloidal type. The CNT-containing solution may be subjected to an ultrasonic treatment for about 10 hours to additionally disperse the CNTs in the solvent.

When coated on the substrate nanowire materials 210 may adhere to surface 102 of substrate 100 to form nanowire layer 200, where layer 200 may include a large number of nanowires where some of the nanowires in nanowire layer 200 across or otherwise make physical and/or electrical contact with other nanowires in nanowire layer 200. By forming nanowire layer 200 on surface 102 of substrate 100, thin film member 300 may be obtained. Thin film member 300 may be utilized for various applications such as, but not limited to, applications that make use of transparent electrodes.

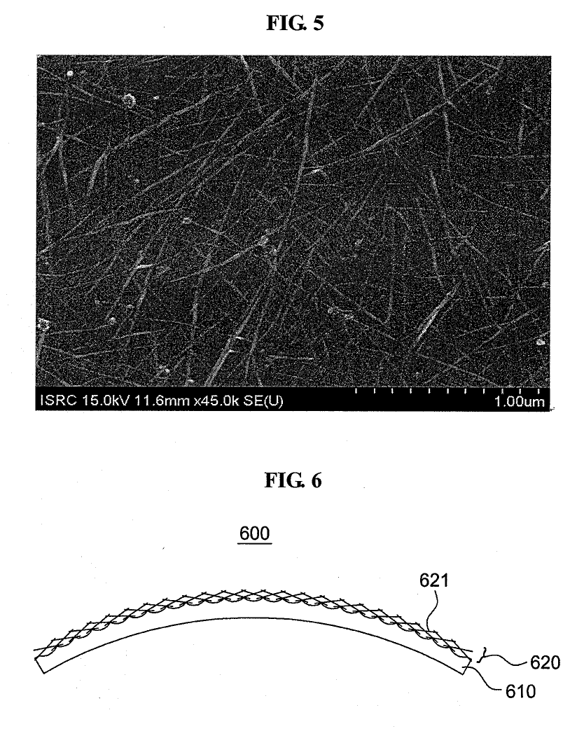

FIG. 4 depicts a sectional diagram obtained by magnifying area ‘A’ of FIG. 3. FIG. 5 depicts a scanning electron microscope (SEM) micrograph showing a nanowire layer. Referring to FIGS. 4 to 5, a first nanowire 211 and a second nanowire 213 may adhere to substrate 100 in a manner where they cross with each other (A) where second nanowire 213 may be positioned on a depressed portion of etched surface. Nanowire layer 200 may be formed in a network where the nanowires are crossed with each other. For example, with reference to FIG. 5, Nanowire layer 200 may be formed in a network exhibiting random crossing between the nanowires of nanowire materials 210.

Again referring to FIG. 4, a contact area 411 between first and second nanowires 211 and 213 may be increased. Also, a separate space 421 apart from substrate 100 in a crossing area between first and second nanowires 211 and 213 may be decreased. Also, contact area 431 between first nanowire 211 and substrate 100 may be increased.

As described above, a transparent electrode having a flexible characteristic and including CNTs as a conductive layer may be manufactured. The transparent electrode possesses excellent durability and electric characteristics. FIG. 6 is a sectional diagram of an illustrative embodiment of a transparent electrode. Referring to FIG. 6, a transparent electrode 600 includes a substrate 610 and a nanowire layer 620. Substrate 610 includes a transparent resin film, by way of non-limiting example, such as a polyethylene terephthalate (PET) film. Nanowire layer 620 includes electrically conductive materials 621. Conductive materials 621 may include, by way of non-limiting example carbon nanotubes (CNTs).

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method for forming a nanowire layer on a substrate comprising: etching the substrate; and, forming nanowires on the substrate.

2. The method of claim 1, wherein the etching comprises etching the substrate by using an ionized gas.

3. A method for forming a nanowire layer, the method comprising:
etching a substrate with an ionized gas;
coating the etched substrate with a solution containing nanowire materials; and
drying the coated substrate.

4. The method of claim 3, wherein the substrate comprises a substrate selected from a group consisting of a silicon substrate, a glass substrate, an oxide substrate and a polymeric substrate.

5. The method of claim 3, wherein the ionized gas comprises at least one element selected from a group consisting of oxygen (O), sulfur (S), selenium (Se), tellurium (Te), fluorine (F), chlorine (Cl), bromine (Br), iodine (I), astatine (At), helium (He), neon (Ne), argon (Ar), krypton (Kr), xenon (Xe), and radon (Rn).

6. The method of claim 3, wherein the nanowire materials comprise carbon nanotubes (CNTs).

7. The method of claim 6, wherein the ionized gas comprises oxygen(O₂).

8. The method of claim 3, wherein the ionized gas comprises an ionized gas formed by applying an electric power of about 150 to about 300 watts to a source gas.

9. The method of claim 3, further comprising:
purifying the nanowire materials using an ultrasonic treatment within an acidic solution, before forming the solution containing nanowire materials.

10. The method of claim 3, wherein the solution containing nanowire materials comprises a colloidal solution.

11. The method of claim 3, wherein coating the etched substrate comprises immersing the substrate in the solution containing nanowire materials.

12. A method for forming a carbon nanotube (CNT) layer, the method comprising:
preparing CNTs;
purifying the CNTs;
dispersing the purified CNTs into a solvent to form a CNT-containing solution;
coating an etched-substrate with the CNT-containing solution; and
drying the coated substrate.

13. The method of claim 12, wherein the purifying the CNTs comprises removing a solvent.

14. The method of claim 13, wherein the removing the solvent comprises comprises performing an ultrasonic treatment on the CNTs within an acidic solution.

15. The method of claim 13, wherein the solvent comprises at least one solvent selected from a group consisting of 1,2-Dichlorobenzene, Chloroform, 1-Methylnaphthalene, 1-Bromo-2-methoylnaphthalene, N-Methylpyrrolidinone, Dimethylformamide, Tetrahydrofuran, 1,2-Dimethylbenzene, Pyridine, Carbon disulfide, and 1,3,5-Trimethylbenzene.

16. A thin film member, comprising:
a substrate etched by an ionized gas; and
a nanowire layer coated on the substrate.

17. The thin film member of claim 16, wherein the substrate comprises a flexible substrate.

18. The thin film member of claim 16, wherein the ionized gas comprises an oxygen gas, and wherein the nanowire materials comprise CNTs.

19. The thin film member of claim 16, wherein the nanowire materials comprise conductive materials.

20. The thin film member of claim 19, wherein the conductive materials comprise CNTs.

21. The thin film member of claim 16, wherein the nanowire layer comprises a network including an area where the nanowire materials are disposed across each other.

22. A transparent electrode, comprising:
a flexible substrate etched by an ionized gas; and
a nanowire layer coated on the flexible substrate, the nanowire layer including CNTs.

23. The transparent electrode of claim 22, wherein the flexible substrate comprises a transparent resin film.

24. The transparent electrode of claim 23, wherein the transparent resin film comprises a polyethylene terephthalate (PET) film.
